(19) United States
(12) Patent Application Publication
(10) Pub. No.: US 2010/0273279 A1
(43) Pub. Date: Oct. 28, 2010

(54) PRODUCTION LINE FOR THE PRODUCTION OF MULTIPLE SIZED PHOTOVOLTAIC DEVICES

(75) Inventors: Tzay-Fa Su, San Jose, CA (US); David Morishige, Los Gatos, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/430,755

(22) Filed: Apr. 27, 2009

(51) Int. Cl. H01L 21/66; H05K 13/00

(52) U.S. Cl. 438/17; 29/729; 257/E21.529

(57) ABSTRACT

Embodiments of the present invention generally relate to a system used to form solar cell devices using processing modules adapted to perform one or more processes in the formation of the solar cell devices. In one embodiment, the system is adapted to form thin film solar cell devices by accepting a large unprocessed substrate and performing multiple deposition, material removal, cleaning, bonding, testing, and sectioning processes to form multiple complete, functional, and tested solar cell devices that can then be shipped to an end user for installation in a desired location to generate electricity. The system is adapted to receive a single large substrate and form multiple silicon thin film solar cell devices from the single large substrate.

### CROSS-REFERENCE TO RELATED APPLICATIONS

This application is related to U.S. application Ser. No. 12/202,199, filed Aug. 29, 2008 (Attorney Docket No. APPM/11141) and U.S. application Ser. No. 12/201,840, filed Aug. 29, 2008 (Attorney Docket No. APPM/11141.02), each of which is incorporated by reference herein.

### BACKGROUND OF THE INVENTION

1. Field of the Invention

Embodiments of the present invention generally relate to a production line used to form multiple sized solar cell devices.

2. Description of the Related Art

Photovoltaic (PV) devices or solar cells are devices which convert sunlight into direct current (DC) electrical power. Typical thin film type PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect. Solar cells may be tiled into larger solar arrays. The solar arrays are created by connecting a number of solar cells and joining them into panels with specific frames and connectors.

Typically, a thin film solar cell includes active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers. There is a need for an improved process of forming a solar cell that has good interfacial contact, low contact resistance and provides a high overall electrical device performance.

With traditional energy source prices on the rise, there is a need for a low cost method of producing electricity using a low cost solar cell device. Conventional solar cell manufacturing processes are highly labor intensive and have numerous interruptions that can affect the production line throughput, solar cell cost, and device yield. For instance, particular solar cell device sizes are needed for particular applications. Conventional solar cell lines are either capable of producing only a single sized solar cell device or require significant downtime to manually convert the solar cell production line processes to accommodate a different substrate size and produce a different sized solar cell device. Thus, there is a need for a production line that is able to perform all phases of the fabrication process for producing multiple sized solar cell devices from a single large substrate.

### SUMMARY OF THE INVENTION

In one embodiment of the present invention, a system for fabricating solar cell devices comprises a substrate receiving module that is adapted to receive a front substrate, a cluster tool having a processing chamber that is adapted to deposit a silicon-containing layer on a surface of the front substrate, a back contact deposition chamber configured to deposit a back contact layer on the silicon-containing layer, a bonding module configured to encapsulate the silicon-containing layer and the back contact layer between the front substrate and a back substrate into a composite structure, a sectioning module configured to section the composite structure into two or more sections, and a system controller for controlling and coordinating functions of each of the substrate receiving module, the cluster tool, the processing chamber, the back contact deposition chamber, the bonding module, and the sectioning module.

In another embodiment of the present invention, a system for fabricating solar cell devices comprises a substrate receiving module that is adapted to receive a front substrate, a cluster tool having a processing chamber that is adapted to deposit a silicon-containing layer on a surface of the front substrate, a back contact deposition chamber configured to deposit a back contact layer on the silicon-containing containing layer, a bonding module configured to encapsulate the silicon-containing layer and the back contact layer between the front substrate and a back substrate into a composite structure, a testing module configured to test performance characteristics of the composite structure, a sectioning module configured to section the tested composite structure into two or more sections, wherein the sectioning module comprises a composite structure positioning mechanism and a composite structure sectioning mechanism, and a system controller for controlling and coordinating functions of each of the substrate receiving module, the cluster tool, the processing chamber, the back contact deposition chamber, the bonding module, the testing module, and the sectioning module.

In yet another embodiment of the present invention, a method of processing a solar cell device cleaning a substrate to remove one or more contaminants from a surface of the substrate, depositing a photoabsorbing layer on the surface of the substrate, removing at least a portion of the photoabsorbing layer from a region on the surface of the substrate, depositing a back contact layer over the photoabsorbing layer on the substrate, removing at least a portion of the back contact layer and the photoabsorbing layer from a region on the surface of the substrate, bonding a back glass substrate to the substrate to form a composite structure, wherein the back contact layer and the photoabsorbing layer are bonded between the back glass substrate and the substrate, attaching one or more junction boxes to the composite structure, testing performance characteristics of the composite structure, and sectioning the composite structure into two or more sections.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process sequence for forming a solar cell device according to one embodiment described herein.

FIG. 2 illustrates a plan view of a solar cell production line according to one embodiment described herein.

FIG. 3A is a side cross-sectional view of a thin film solar cell device according to one embodiment described herein.

FIG. 3B is a side cross-sectional view of a thin film solar cell device according to one embodiment described herein.

FIG. 3C is a plan view of a composite solar cell structure according to one embodiment described herein.

FIG. 3D is a cross-sectional view of along Section A-A of FIG. 3C.

FIG. 3E is a side cross-sectional view of a thin film solar cell device according to one embodiment described herein.

FIGS. 4A-4E are schematic plan views illustrating the sequencing of a sectioning module according to one embodiment of the present invention.

FIGS. 5A-5C are schematic side views of portions of the sectioning module illustrating a sequence of sectioning a composite solar cell structure according to one embodiment of the present invention.

FIG. 6 is a schematic depiction of a laser cutting device for sectioning a composite solar cell structure according to one embodiment of the present invention.

### DETAILED DESCRIPTION

Embodiments of the present invention generally relate to a system used to form solar cell devices using processing modules adapted to perform one or more processes in the formation of the solar cell devices. In one embodiment, the system is adapted to form thin film solar cell devices by accepting a large unprocessed substrate and performing multiple deposition, material removal, cleaning, bonding, testing, and sectioning processes to form multiple complete, functional, and tested solar cell devices that can then be shipped to an end user for installation in a desired location to generate electricity.

In one embodiment, the system is capable of accepting a single large unprocessed substrate and producing multiple smaller solar cell devices. In one embodiment, the system is capable of changing the sizes of the solar cell devices produced from the single large substrate without manually moving or altering any of the system modules. While the discussion below primarily describes the formation of silicon thin film solar cell devices, this configuration is not intended to limit the scope of the invention since the apparatus and methods disclosed herein can also be used to form, test, and analyze other types of solar cell devices, such as III-V type solar cells, thin film chalcogenide solar cells (e.g., CIGS, CdTe cells), amorphous or nanocrystalline silicon solar cells, photochemical type solar cells (e.g., dye sensitized), crystalline silicon solar cells, organic type solar cells, or other similar solar cell devices.

In one embodiment, the system is generally an arrangement of automated processing modules and automation equipment used to form solar cell devices that are interconnected by an automated material handling system. In one embodiment, the system is a fully automated solar cell device production line that reduces or removes the need for human interaction and/or labor intensive processing steps to improve the device reliability, process repeatability, and cost of ownership of the formation process.

In one configuration, the system is adapted to form multiple silicon thin film solar cell devices from a single large substrate and generally comprises a substrate receiving module that is adapted to accept an incoming substrate, one or more absorbing layer deposition cluster tools having at least one processing chamber that is adapted to deposit a silicon-containing layer on a processing surface of the substrate, one or more back contact deposition chambers that are adapted to deposit a back contact layer on the processing surface of the substrate, one or more material removal chambers that are adapted to remove material from the processing surface of the substrate, an encapsulation device that is adapted to form a composite solar cell structure from the substrate, an autoclave module that is adapted to heat and expose the composite solar cell structure to a pressure greater than atmospheric pressure, a junction box attaching region to attach a connection element that allows the solar cell device to be connected to external components, one or more quality assurance modules adapted to test and qualify the formed solar cell device, and one or more sectioning modules used to section the formed solar cell device into multiple smaller solar cell devices. The one or more quality assurance modules may include a solar simulator, a parametric testing module, and a shunt bust and qualification module.

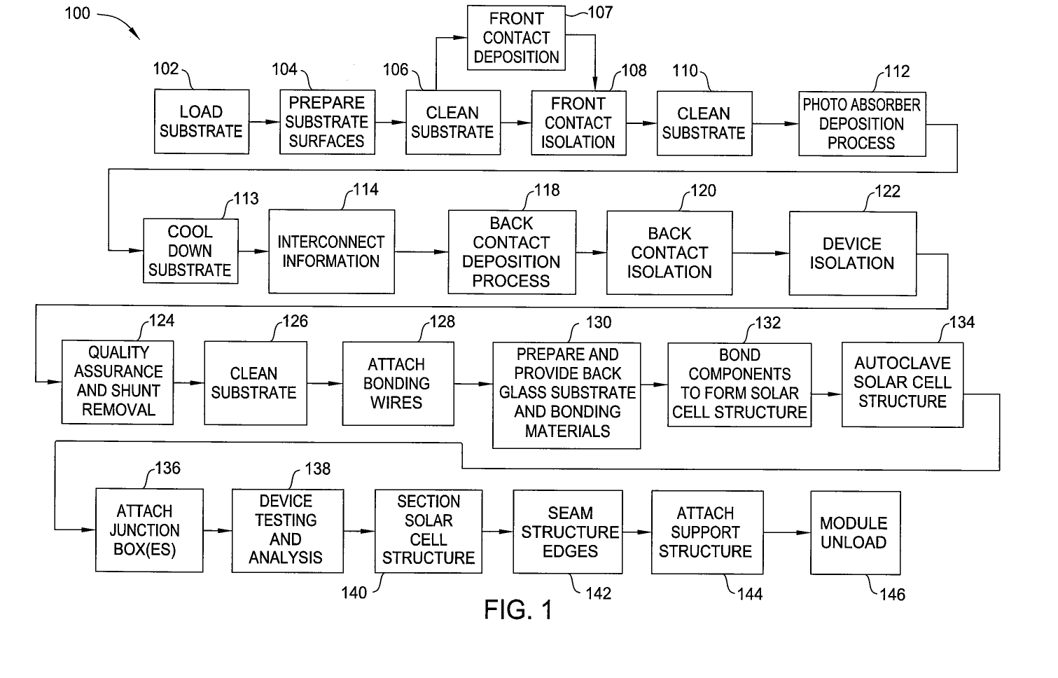

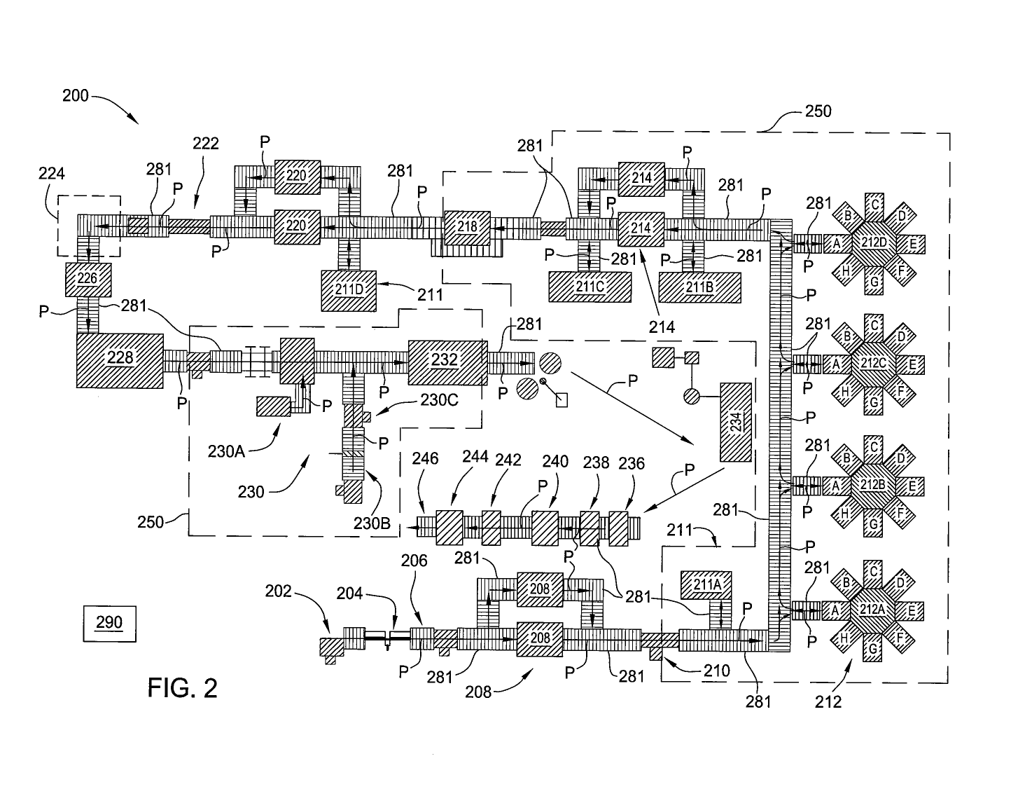

FIG. 1 illustrates one embodiment of a process sequence 100 that includes a plurality of steps (i.e., steps 102-146) that are used to form a solar cell device in a novel solar cell production line 200 described herein. The configuration, number of processing steps, and order of the processing steps in the process sequence 100 is not intended to limit the scope of the invention described herein. FIG. 2 is a plan view of one embodiment of the production line 200, which is intended to illustrate some of the typical processing modules and process flows through the system and other related aspects of the system design, and is thus not intended to limit the scope of the invention described herein.

In general, a system controller 290 may be used to control one or more components found in the solar cell production line 200. The system controller 290 is generally designed to facilitate the control and automation of the overall solar cell production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 290 determines which tasks are performable on a substrate. Preferably, the program is software readable by the system controller 290 that includes code to perform tasks relating to monitoring, execution and control of the movement, support, and/or positioning of a substrate along with the various process recipe tasks and various chamber process recipe steps being performed in the solar cell production line 200. In one embodiment, the system controller 290 also contains a plurality of programmable logic controllers (PLC's) that are used to locally control one or more modules in the solar cell production, and a material handling system controller (e.g., PLC or standard computer) that deals with the higher level strategic movement, scheduling and running of the complete solar cell production line.

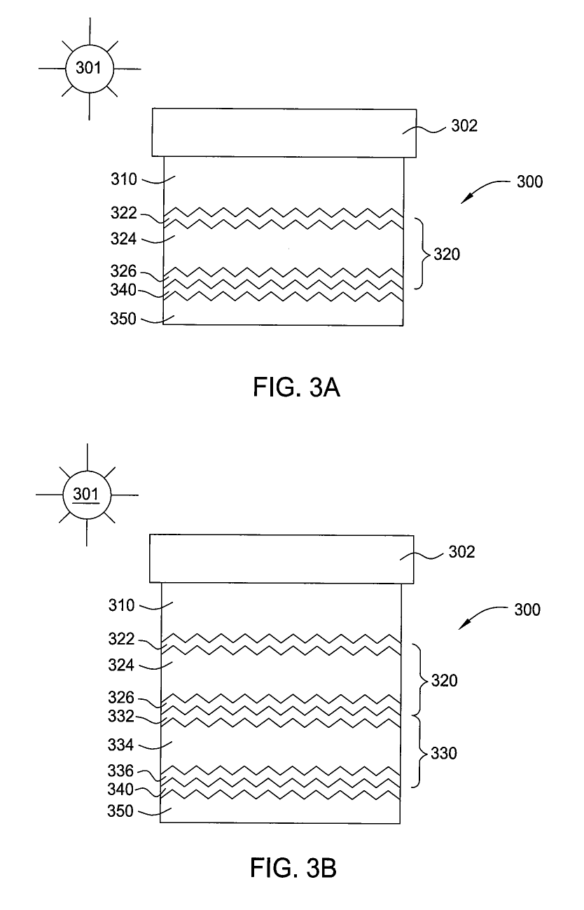

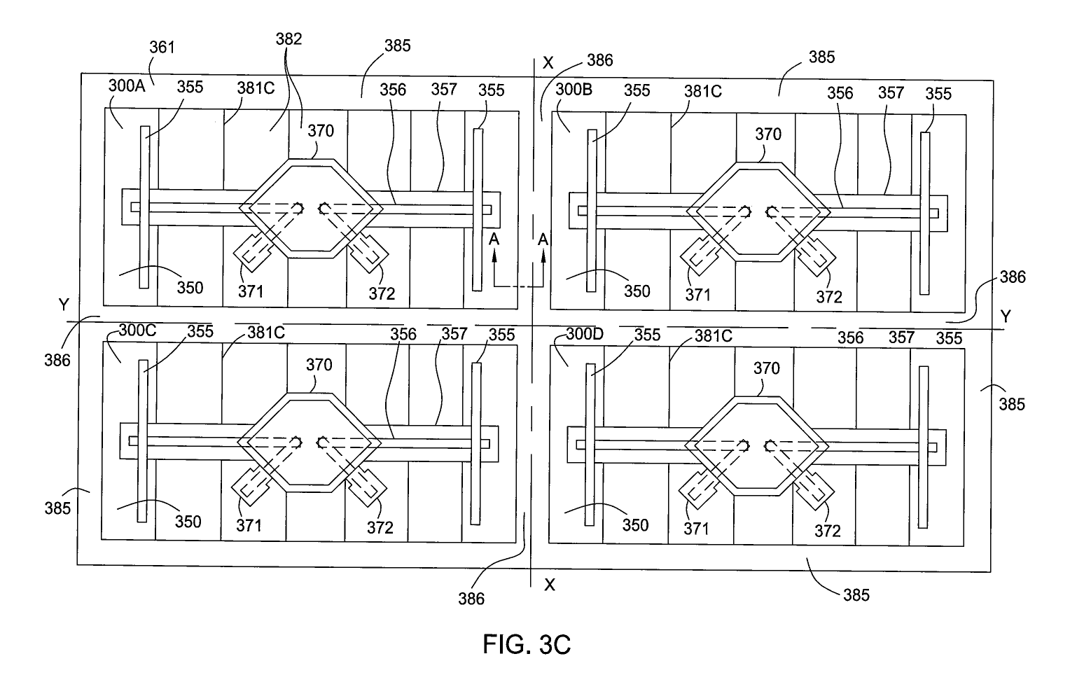

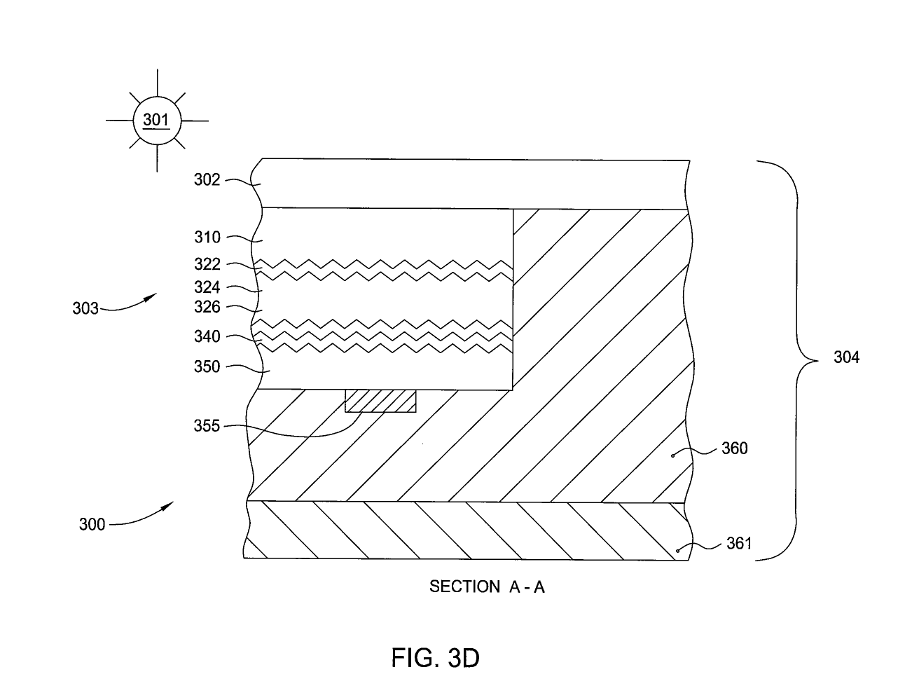

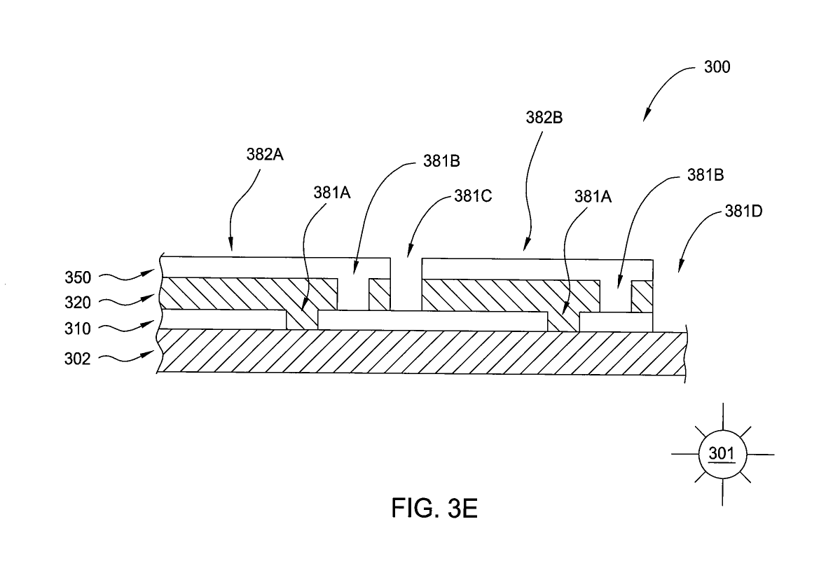

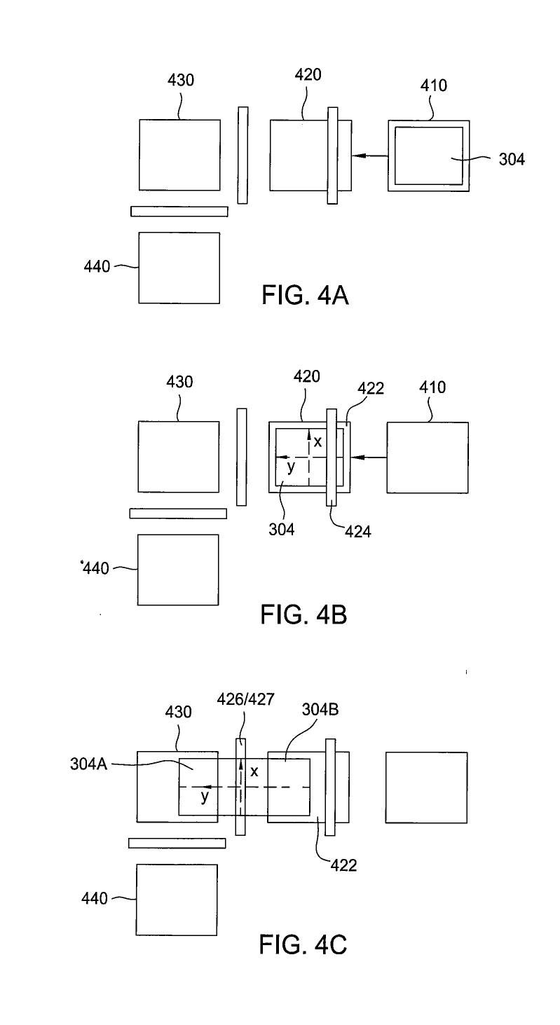

Examples of a solar cell 300 that can be formed using the process sequence(s) illustrated in FIG. 1 and the components illustrated in the solar cell production line 200 are illustrated in FIGS. 3A-3E. FIG. 3A is a simplified schematic diagram of a single junction amorphous or micro-crystalline silicon solar cell 300 that can be formed and analyzed in the system described below. As shown in FIG. 3A, the single junction amorphous or micro-crystalline silicon solar cell 300 is oriented toward a light source or solar radiation 301. The solar cell 300 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 300 further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340.

To improve light absorption by enhancing light trapping, the substrate and/or one or more of the thin films formed thereover may be optionally textured by wet, plasma, ion, and/or mechanical processes. For example, in the embodiment shown in FIG. 3A, the first TCO layer 310 is textured, and the subsequent thin films deposited thereover generally follow the topography of the surface below it.

In one configuration, the first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å. The back contact layer 350 may include, but is not limited to a material selected from Al, Ag, Ti, Cr, Au, Cu, Pt, alloys thereof, and combinations thereof.

FIG. 3B is a schematic diagram of an embodiment of a solar cell 300, which is a multi-junction solar cell that is oriented toward the light or solar radiation 301. The solar cell 300 comprises a substrate 302, such as a glass substrate, polymer substrate, metal substrate, or other suitable substrate, with thin films formed thereover. The solar cell 300 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340. In the embodiment shown in FIG. 3B, the first TCO layer 310 is textured, and the subsequent thin films deposited thereover generally follow the topography of the surface below it.

The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å.

The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to, a material selected from Al, Ag, Ti, Cr, Au, Cu, Pt, alloys thereof, and combinations thereof.

FIG. 3C is a plan view that schematically illustrates an example of the rear surface of a composite structure having four formed solar cells 300 (e.g., smaller solar cells 300A-300D) that have been formed on a single substrate 302, as may be produced in the production line 200. The smaller solar cells 300A-300D are formed by removing sections (e.g., reference numeral 386) of the deposited layers (e.g., reference numerals 310-350) to form two or more smaller solar cells on the substrate 302. Although four smaller solar cells 300A-300B are shown, this is not intended to limit the scope of the invention as the invention described herein is equally applicable to any number of solar cells 300 formed on a single large substrate 302. For instance, the production line 200 may be capable of producing a single 5.7 m² solar cell 300, two 2.8 m² smaller solar cells 300, or four 1.4 m² smaller solar cells 300 from a single 5.7 m² substrate 302 via process sequence 100.

FIG. 3D is a side cross-sectional view of a portion of one of the smaller solar cells 300A illustrated in FIG. 3C (see section A-A). While FIG. 3D illustrates the cross-section of a single junction cell similar to the configuration described in FIG. 3A, this is not intended to limit the scope of the invention described herein.

As shown in FIGS. 3C and 3D, each of the smaller solar cells 300A-300D may contain a portion of the substrate 302, portions of the deposited solar cell device elements (e.g., reference numerals 310-350), one or more internal electrical connections (e.g., side buss 355, cross-buss 356), a portion of the layer of bonding material 360, a portion of the back glass substrate 361, and a junction box 370. The junction box 370 may include two connection points 371, 372 that are electrically connected to portions of the smaller solar cell 300A-300D through the side buss 355 and the cross-buss 356, which are in electrical communication with the back contact layer 350 and active regions (i.e., reference numeral 320) of each of the smaller solar cells 300A-300D.

To avoid confusion relating to the actions specifically performed on the substrates 302 in the discussion below, a substrate 302 having one or more of the deposited layers (e.g., reference numerals 310-350) and/or one or more internal electrical connections (e.g., side buss 355, cross-buss 356) disposed thereon is generally referred to as a device substrate 303. Similarly, a device substrate 303 that has been bonded to a back glass substrate 361 using a layer of bonding material 360 is referred to as a composite solar cell structure 304. In general, configurations in which a single solar cell is formed across the entire substrate 302 are specifically noted. Otherwise, it is intended that the phrase “solar cell 300” generally signifies one of the two or more smaller solar cells (e.g., reference numerals 300A-300D in FIG. 3C) formed on portions of the larger substrate 302 using the steps described below.

FIG. 3E is a schematic cross-section of a solar cell 300 illustrating various scribed regions used to form the individual cells 382A-382B within the solar cell 300. In one example, as shown in FIG. 3C, there are nine individual cells 382 formed in the smaller solar cell 300A. As illustrated in FIG. 3E, the solar cell 300 includes a transparent substrate 302, a first TCO layer 310, a first p-i-n junction 320, and a back contact layer 350. Four scribing steps, such as laser scribing steps, may be performed to produce trenches 381A, 381B, and 381C, and 381D which are generally required to form a high efficiency solar cell device. Although formed together on the substrate 302, the individual cells 382A and 382B are isolated from each other by the insulating trench 381C formed in the back contact layer 350 and the first p-i-n junction 320. In addition, the trench 381B is formed in the first p-i-n junction 320 so that the back contact layer 350 is in electrical contact with the first TCO layer 310. In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. In addition, the trench 381D is formed through the back contact layer 350, the first p-i-n junction 320, and the first TCO layer 310 both for edge isolation and separation of individual smaller solar cells 300A-300D on the substrate 302. While a single junction type solar cell is illustrated in FIG. 3E this configuration is not intended to limit the scope of the invention described herein.

### General Solar Cell Formation Process Sequence

Referring to FIGS. 1 and 2, the process sequence 100 generally starts at step 102 in which a substrate 302 is loaded into the loading module 202 found in the solar cell production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar cell device and thus reduces the solar cell device cost, facilities costs, and production costs of the finally formed solar cell device. However, typically, it is advantageous to receive “raw” substrates 302 that have a transparent conducting oxide (TCO) layer (e.g., first TCO layer 310) already deposited on a surface of the substrate 302 before it is received into the system in step 102. If a conductive layer, such as TCO layer, is not deposited on the surface of the “raw” substrates then a front contact deposition step (step 107), which is discussed below, needs to be performed on a surface of the substrate 302.

In one embodiment, the substrates 302 or 303 are loaded into the solar cell production line 200 in a sequential fashion, and thus do not use a cassette or batch style substrate loading system. A cassette style and/or batch loading type system that requires the substrates to be un-loaded from the cassette, processed, and then returned to the cassette before moving to the next step in the process sequence can be time consuming and decrease the solar cell production line throughput. The use of batch processing does not facilitate certain embodiments of the present invention, such as fabricating multiple solar cell devices from a single substrate. Additionally, the use of a batch style process sequence generally prevents the use of an asynchronous flow of substrates through the production line, which is believed to provide improved substrate throughput during steady state processing and when one or more modules are brought down for maintenance or due to a fault condition. Generally, batch or cassette based schemes are not able to achieve the throughput of the production line described herein during normal operation, or more particularly, when one or more processing modules are brought down for maintenance, since the queuing and loading of substrates can require a significant amount of overhead time.

In step 104, the surfaces of the substrate 302 are prepared to prevent yield issues later on in the process. In one embodiment of step 104, the substrate is inserted into a front end seaming module 204 that is used to prepare the edges of the substrate 302 or 303 to reduce the likelihood of damage, such as chipping or particle generation from occurring during the subsequent processes. Damage to the substrate 302 or 303 can affect device yield and the cost to produce a usable solar cell device. In one embodiment, the front end seaming module 204 is used to round or bevel the edges of the substrate 302 or 303. In one embodiment, a diamond impregnated belt or disc is used to grind the material from the edges of the substrate 302 or 303. In another embodiment, a grinding wheel, grit blasting, or laser ablation technique is used to remove the material from the edges of the substrate 302 or 303.

Next the substrate 302 or 303 is transported to the cleaning module 206, in which step 106, or a substrate cleaning step, is performed on the substrate 302 or 303 to remove any contaminants found on the surface of thereof. Common contaminants may include materials deposited on the substrate 302 or 303 during the substrate forming process (e.g., glass manufacturing process) and/or during shipping or storing of the substrates 302 or 303. Typically, the cleaning module 206 uses wet chemical scrubbing and rinsing steps to remove any undesirable contaminants.

In one example, the process of cleaning the substrate 302 or 303 may occur as follows. First, the substrate 302 or 303 enters a contaminant removal section of the cleaning module 206 from either a transfer table or an automation device 281. In general, the system controller 290 establishes the timing for each substrate 302 or 303 that enters the cleaning module 206. The contaminant removal section may utilize dry cylindrical brushes in conjunction with a vacuum system to dislodge and extract contaminants from the surface of the substrate 302. Next, a conveyor within the cleaning module 206 transfers the substrate 302 or 303 to a pre-rinse section, where spray tubes dispense hot de-ionized (DI) water at a temperature, for example, of 50° C. from a DI water heater onto a surface of the substrate 302 or 303. Commonly, since the device substrate 303 has a TCO layer disposed thereon, and since TCO layers are generally electron absorbing materials, DI water is used to avoid any traces of possible contamination and ionizing of the TCO layer. Next, the rinsed substrate 302, 303 enters a wash section. In the wash section, the substrate 302 or 303 is wet-cleaned with a brush (e.g., perlon) and hot water. In some cases a detergent (e.g., AlconoX™, Citrajet™, Detojet™, Transene™, and Basic H™), surfactant, pH adjusting agent, and other cleaning chemistries are used to clean and remove unwanted contaminants and particles from the substrate surface. A water re-circulation system recycles the hot water flow. Next, in a final rinse section of the cleaning module 206, the substrate 302 or 303 is rinsed with water at ambient temperature to remove any traces of contaminants. Finally, in a drying section, an air blower is used to dry the substrate 302 or 303 with hot air. In one configuration, a deionization bar is used to remove the electrical charge from the substrate 302 or 303 at the completion of the drying process.

In one embodiment of step 108, the TCO layer 310 is scribed to form separate, electrically isolated cells on the surface of the substrate 302. Contamination particles on the surface of the TCO layer 310 and/or on the bare surface of the substrate 302 can interfere with the scribing procedure. In laser scribing, for example, if the laser beam runs across a particle, it may be unable to scribe a continuous line, and a short circuit between cells may result. In addition, any particulate debris present in the scribed pattern and/or on the TCO layer 310 after scribing can cause shunting and non-uniformities between layers. Therefore, a well-defined and well-maintained process is needed to ensure that contamination is removed throughout the production process. In one embodiment, the cleaning module 206 is available from the Energy and Environment Solutions division of Applied Materials in Santa Clara, Calif.

Referring to FIGS. 1 and 2, in one embodiment, prior to performing step 108 the substrates 302 are transported to a front end processing module (not illustrated in FIG. 2) in which a front contact formation process, or step 107, is performed on the substrate 302. In one embodiment, the front end processing module is similar to the processing module 218 discussed below. In step 107, the one or more substrate front contact formation steps may include one or more preparation, etching, and/or material deposition steps that are used to form front contact regions on a bare solar cell substrate 302. In one embodiment, step 107 generally comprises one or more physical vapor deposition (PVD) steps that are used to form the front contact region on a surface of the substrate 302. In one embodiment, the front contact region includes the transparent conducting oxide (TCO) layer 310 that may contain a metal element selected from zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact formation steps. In another embodiment, one or more chemical vapor deposition (CVD) steps are used to form the front contact region on a surface of the substrate 302.

Next the device substrate 303 is transported to the scribe module 208 in which step 108, or a front contact isolation step, is performed on the device substrate 303 to electrically isolate different regions of the device substrate 303 surface from each other. In step 108, material is removed from the device substrate 303 surface by use of a material removal step, such as a laser ablation process. The success criteria for step 108 are to achieve good cell-to-cell and cell-to-edge isolation while minimizing the scribe area. In one embodiment, a Nd:vanadate (Nd:YVO₄) laser source is used ablate material from the device substrate 303 surface to form lines that electrically isolate one region of the device substrate 303 from the next. In one embodiment, the laser scribe process performed during step 108 uses a 1064 nm wavelength pulsed laser to pattern the material disposed on the substrate 302 to isolate each of the individual cells (e.g., individual cells 382A and 382B) that make up the solar cell 300. In one embodiment, a 5.7 m² substrate laser scribe module available from Applied Materials, Inc. of Santa Clara, Calif. is used to provide simple reliable optics and substrate motion for accurate electrical isolation of regions of the device substrate 303 surface. In another embodiment, a water jet cutting tool or diamond scribe is used to isolate the various regions on the surface of the device substrate 303.

In one aspect, it is desirable to assure that the temperature of the device substrates 303 entering the scribe module 208 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the device substrate 303 temperature to about 25±0.5° C.

Next, the device substrate 303 is transported to the cleaning module 210 in which step 110, or a pre-deposition substrate cleaning step, is performed on the device substrate 303 to remove any contaminants found on the surface of the device substrate 303 after performing the front contact isolation step (step 108). Typically, the cleaning module 210 uses wet chemical scrubbing and rinsing steps to remove any undesirable contaminants found on the device substrate 303 surface after performing the cell isolation step. In one embodiment, a cleaning process, similar to the processes described in step 106 above, is performed on the device substrate 303 to remove any contaminants on the surface(s) of the device substrate 303.

Next, the device substrate 303 is transported to the processing module 212 in which step 112, which comprises one or more photoabsorber deposition steps, is performed on the device substrate 303. In step 112, the one or more photoabsorber deposition steps may include one or more preparation, etching, and/or material deposition steps that are used to form various regions of the solar cell device. Step 112 generally comprises a series of sub-processing steps that are used to form one or more p-i-n junctions, such as the first p-i-n junction 320 and the second p-i-n junction 330. In one embodiment, the one or more p-i-n junctions comprise amorphous silicon and/or microcrystalline silicon materials.

In general, the one or more processing steps are performed in one or more cluster tools (e.g., cluster tools 212A-212D) found in the processing module 212 to form one or more layers on the device substrate 303. In one embodiment, the device substrate 303 is transferred to an accumulator 211A prior to being transferred to one or more of the cluster tools 212A-212D. In one embodiment, in cases where the solar cell device is formed to include multiple junctions, such as the tandem junction solar cell 300 illustrated in FIG. 3B, the cluster tool 212A in the processing module 212 is adapted to form the first p-i-n junction 320 and cluster tools 212B-212D are configured to form the second p-i-n junction 330.

In one embodiment of the process sequence 100, a cool down step, or step 113, is performed after step 112 has been performed. The cool down step is generally used to stabilize the temperature of the device substrate 303 to assure that the processing conditions seen by each device substrate 303 in the subsequent processing steps are repeatable. Generally, the temperature of the device substrate 303 exiting the processing module 212 could vary by many degrees Celsius and exceed a temperature of 50° C., which can cause variability in the subsequent processing steps and solar cell performance.

In one embodiment, the cool down step 113 is performed in one or more of the substrate supporting positions found in one or more accumulators 211. In one configuration of the production line, as shown in FIG. 2, the processed device substrates 303 may be positioned in one of the accumulators 211B for a desired period of time to control the temperature of the device substrate 303. In one embodiment, the system controller 290 is used to control the positioning, timing, and movement of the device substrates 303 through the accumulator(s) 211 to control the temperature of the device substrates 303 before proceeding down stream through the production line.

Next, the device substrate 303 is transported to the scribe module 214 in which an interconnect formation step, or step 114, is performed on the device substrate 303 to electrically isolate various regions of the device substrate 303 surface from each other. In step 114, material is removed from the device substrate 303 surface by use of a material removal step, such as a laser ablation process. In one embodiment, an Nd:vanadate (Nd:YVO₄) laser source is used ablate material from the substrate surface to form lines that electrically isolate one individual cell from the next. In one embodiment, a 5.7 m² substrate laser scribe module available from Applied Materials, Inc. is used to perform the accurate scribing process. In one embodiment, the laser scribe process performed during step 114 uses a 532 nm wavelength pulsed laser to pattern the material disposed on the device substrate 303 to isolate the individual cells that make up the solar cell 300. As shown in FIG. 3E, in one embodiment, the trench 381B is formed in the first p-i-n junction 320 layers by use of a laser scribing process during step 114. In another embodiment, a water jet cutting tool or diamond scribe is used to isolate the various regions on the surface of the device substrate 303.

In one aspect, it is desirable to assure that the temperature of the device substrates 303 entering the scribe module 214 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the substrate temperature to about 25±0.5° C.

In one embodiment, the solar cell production line 200 has at least one accumulator 211 positioned after the scribe module(s) 214. During production accumulators 211C may be used to provide a ready supply of device substrates 303 to a processing module 218, and/or provide a collection area where device substrates 303 coming from the processing module 212 can be stored if the processing module 218 goes down or cannot keep up with the throughput of the scribe module(s) 214.

In one embodiment, it is generally desirable to monitor and/or actively control the temperature of the device substrates 303 exiting the accumulators 211C to assure that the results of the back contact formation step 120 are repeatable. In one aspect, it is desirable to assure that the temperature of the device substrates 303 exiting the accumulators 211C or arriving at the processing module 218 are at a temperature in a range between about 20° C. and about 26° C. In one embodiment, it is desirable to control the substrate temperature to about 25±0.5° C. In one embodiment, it is desirable to position one or more accumulators 211C that are able to retain at least about 80 device substrates 303.

Next, the device substrate 303 is transported to the processing module 218 in which one or more back contact formation steps, or step 118, are performed on the device substrate 303. In step 118, the one or more back contact formation steps may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 350. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the device substrate 303.

In one embodiment, the solar cell production line 200 has at least one accumulator 211 positioned after the processing module 218. During production, the accumulators 211D may be used to provide a ready supply of device substrates 303 to the scribe modules 220, and/or provide a collection area where the device substrates 303 coming from the processing module 218 can be stored if the scribe modules 220 go down or can not keep up with the throughput of the processing module 218.

In one embodiment it is generally desirable to monitor and/or actively control the temperature of the device substrates 303 exiting the accumulators 211D to assure that the results of the back contact formation step 120 are repeatable. In one aspect, it is desirable to assure that the temperature of the device substrates 303 exiting the accumulators 211D or arriving at the scribe module 220 are at a temperature in a range between about 20° C. and about 26° C. In one embodiment, it is desirable to control the substrate temperature to about 25±0.5° C. In one embodiment, it is desirable to position one or more accumulators 211C that are able to retain at least about 80 device substrates 303.

Next, the device substrate 303 is transported to the scribe module 220 in which step 120, or a back contact isolation step, is performed on the device substrate 303 to electrically isolate the individual cells disposed on the substrate surface from each other. In step 120, material is removed from the substrate surface by use of a material removal step, such as a laser ablation process. In one embodiment, an Nd:vanadate (Nd:YVO₄) laser source is used ablate material from the device substrate 303 surface to form lines that electrically isolate one individual cell from the next. In one embodiment, a 5.7 m² substrate laser scribe module, available from Applied Materials, Inc., is used to accurately scribe the desired regions of the device substrate 303. In one embodiment, the laser scribe process performed during step 120 uses a 532 nm wavelength pulsed laser to pattern the material disposed on the device substrate 303 to isolate the individual cells that make up the solar cell 300. As shown in FIG. 3E, in one embodiment, the trench 381C is formed in the first p-i-n junction 320 and back contact layer 350 by use of a laser scribing process.

In one aspect, it is desirable to assure that the temperature of the device substrates 303 entering the scribe module 220 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the substrate temperature to about 25±0.5° C.

Next, the device substrate 303 is transported to the solar cell device isolation module 222 in which device isolation steps, or step 122, are performed on the device substrate 303 to separate regions of the deposited layers to form multiple smaller solar cells 300 (e.g., reference numerals 300A-330D) on the substrate 302,as shown in FIGS. 3C and 3D. In step 122, material is removed from the surface of the substrate 302 by use of a material removal step, such as a laser ablation process. As shown in FIG. 3C, the material removal device is configured to remove material from an edge region 385 and sectioning regions 386 to form the smaller solar cells 300A-300D. The sectioning regions 386 are configured to electrically and physically isolate two or more formed solar cells 300 from each other. After processing, the edge region 385 and sectioning regions 386 are generally free of the materials deposited on the surface of the substrate 302 (e.g., layers 310-350) to form isolated solar cells 300 and allow the bonding material 360 to form a bond to the surface of the substrate 302 in a subsequent processing step (step 132). In one embodiment, an edge region 385 is between about 5 and about 15 mm in width and a sectioning region 386 is between about 10 mm and about 30 mm in width, where the widths are measured parallel to the surface of the substrate 302. In one example, the edge region 385 is about 10 mm in width and the sectioning region 386 is about 20 mm in width.

In one embodiment, an Nd:vanadate (Nd:YVO₄) or Nd:YAG laser source is used to ablate material from the substrate 302 surface to form regions that electrically isolate one of the smaller solar cells 300A-300D from the other. In one embodiment, the laser ablation process performed during step 122 uses a 1064 nm wavelength pulsed laser to pattern the material disposed on the substrate 302 to isolate multiple smaller solar cells 300 formed on the substrate 302 from one another as well as isolate the edges of the individual smaller solar cells 300. As shown in FIG. 3E, in one embodiment, the trench 381D is formed through the front TCO layer 310, the first p-i-n junction 320, and the back contact layer 350 by use of a laser ablation process. In another embodiment, a water jet cutting tool or a diamond scribe is used to provide edge isolation and to isolate the multiple smaller solar cells 300 from one another. In one embodiment, a 5.7 m² substrate laser ablation module, available from Applied Materials, Inc., is used to accurately ablate the desired regions of the device substrate 303.

In one aspect, it is desirable to assure that the temperature of the device substrates 303 entering the solar cell device isolation module 222 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the substrate temperature to about 25±0.5° C.

Next, the device substrate 303 is transported to the quality assurance module 224 in which step 124, or quality assurance and/or shunt removal steps, are performed on regions of the device substrate 303 to assure that the devices formed on the substrate surface meet a desired quality standard and, in some cases, to correct defects in the formed device. In one embodiment, the analyzed and processed regions of the device substrate 303 include each of the individual cells (e.g., individual cells 382A-382B in FIG. 3E) formed within each of the multiple smaller solar cells 300 (e.g., reference numerals 300A-330D). In step 124, a probing device is used to measure the quality and material properties of the formed solar cell device by use of one or more substrate contacting probes. In one embodiment, the quality assurance module 224 projects a low level of light at the p-i-n junctions of the solar cells and uses the one more probes to measure the output of the cells to determine the electrical characteristics of the formed solar cell devices.

If the module detects a defect in the formed device, it can take corrective actions to correct the defects in the formed smaller solar cells 300 on the device substrate 303. In one embodiment, if a short or other similar defect is found, a reverse bias may be applied between regions on the substrate surface to control and or correct one or more of the defectively formed regions of the solar cell device. During the correction process the reverse bias generally delivers a voltage high enough to cause the defects in the solar cells to be corrected. In one example, if a short is found between supposedly isolated regions of the device substrate 303 the magnitude of the reverse bias may be raised to a level that causes the conductive elements in areas between the isolated regions to change phase, decompose, or become altered in some way to eliminate or reduce the magnitude of the electrical short.

In one embodiment of the process sequence 100, the quality assurance module 224 and factory automation system are used together to resolve quality issues found in a formed device substrate 303 during the quality assurance testing. In one case, a device substrate 303 may be sent back upstream in the processing sequence to allow one or more of the fabrication steps to be re-performed on the device substrate 303 (e.g., back contact isolation step (step 120)) to correct one or more quality issues with the processed device substrate 303.

Next, the device substrate 303 is transported to the cleaning module 226 in which step 126, or a pre-lamination cleaning step, is performed on the device substrate 303 to remove any contaminants found on the surface of the multiple smaller solar cells 300 formed on the device substrate 303. Typically, the cleaning module 226 uses wet chemical scrubbing and rinsing steps to remove any undesirable contaminants found on the substrate surface. In one embodiment, a cleaning process similar to the processes described in step 106 is performed on the substrate 303 to remove any contaminants on the surface(s) of the substrate 303, such as the edge region 385, sectioning regions 386, back contact layer 350, trenches 381C, and front surface and edges of the substrate 302. In one embodiment, optical inspection or electrical conductivity tests are performed on various portions of the edge region 385 or sectioning regions 386 after step 126 to assure that all of the desired material has been removed. In one embodiment of the processing sequence 100, step 126 is performed on the device substrate 303 prior to performing step 124.

Next, the substrate 303 is transported to a bonding wire attach module 228 in which step 128, or a bonding wire attach step, is performed on the device substrate 303. Step 128 is used to attach the various wires/leads required to connect the various external electrical components to the formed smaller solar cell devices formed on the substrate 302. Typically, the bonding wire attach module 228 is an automated wire bonding tool that is used to reliably and quickly form the numerous interconnects that are often required to form the solar cells 300 formed in the production line 200. In one embodiment, the bonding wire attach module 228 is used to form the side-buss 355 (FIG. 3C) and cross-buss 356 on the formed back contact region (step 118) of each of the smaller solar cells 300. In this configuration the side-buss 355 may be a conductive material that can be affixed, bonded, and/or fused to the back contact layer 350 found in the back contact region to form a good electrical contact.

In one embodiment, the side-buss 355 and cross-buss 356 each comprise a metal strip, such as copper tape, a nickel coated silver ribbon, a silver coated nickel ribbon, a tin coated copper ribbon, a nickel coated copper ribbon, or other conductive material that can carry the current delivered by each solar cell and be reliably bonded to the metal layer in the back contact region. In one embodiment, the metal strip is between about 2 mm and about 10 mm wide and between about 1 mm and about 3 mm thick. The cross-buss 356, which is electrically connected to the side-buss 355 at the junctions, can be electrically isolated from the back contact layer 350 of each of the smaller solar cells 300 by use of an insulating material 357, such as an insulating tape, as shown in FIG. 3C. The ends of each of the cross-busses 356 generally have one or more leads that are used to connect the side-buss 355 and the cross-buss 356 to the electrical connections found in a junction box 370, which is used to connect the formed solar cell to the other external electrical components.

In step 130, a bonding material 360 (FIG. 3D) and “back glass” substrate 361 are prepared for delivery into the solar cell formation process (Le., process sequence 100). The preparation process is generally performed in the glass lay-up module 230, which generally comprises a material preparation module 230A, a glass loading module 230B, and a glass cleaning module 230C. The back glass substrate 361 is bonded onto the device substrate 303 formed in steps 102-128 above by use of a laminating process (step 132 discussed below). In general, step 130 requires the preparation of a polymeric material that is to be placed between the back glass substrate 361 and the deposited layers on the device substrate 303 having the edge region 385 and sectioning regions 386 formed thereon to form a hermetic seal between the back glass 361 and portions of the exposed substrate 302 surface during a subsequent step (step 132). The formed hermetic seal prevents the environment from attacking each of the smaller solar cells 300A-300D (FIG. 3C) after they have been separated in a subsequent processing step (step 140), during each of their useful lives.

Referring to FIGS. 1 and 2, step 130 generally comprises a series of sub-steps. First, a bonding material 360 is prepared in the material preparation module 230A. The bonding material 360 is then placed over the device substrate 303. Next, the back glass substrate 361 is loaded into the glass loading module 230B and is washed by use of the cleaning module 230C. Finally, the back glass substrate 361 is placed over the bonding material 360 and the device substrate 303.

In one embodiment, the material preparation module 230A is adapted to receive the bonding material 360 in a sheet form and perform one or more cutting operations to provide a bonding material, such as Polyvinyl Butyral (PVB) or Ethylene Vinyl Acetate (EVA) that is sized to cover the surface of the substrate 302 on which the deposited layers (e.g., reference numerals 310-350) are disposed. In general, when using bonding materials 360 that are polymeric, it is desirable to control the temperature (e.g., 16-18° C.) and relative humidity (e.g., RH 20-22%) of the solar cell production line 200 where the bonding material 360 is stored and integrated into the solar cell device to assure that the attributes of the bond formed in the bonding module 232 are repeatable and the dimensions of the polymeric material are stable. It is generally desirable to store the bonding material prior to use in temperature and humidity controlled area (e.g., T=6-8° C.; RH=20-22%). The tolerance stack up of the various components in the bonded device (Step 132) can be an issue when forming large solar cells. Therefore, accurate control of the bonding material properties and tolerances of the cutting process are required to assure that a reliable hermetic seal is formed. In one embodiment, PVB may be used to advantage due to its UV stability, moisture resistance, thermal cycling, good US fire rating, compliance with International Building Code, low cost, and reworkable thermo-plastic properties.

In one part of step 130, the bonding material 360 is transported and positioned over the back contact layer 350, the side-buss 355 (FIG. 3C), and the cross-buss 356 (FIG. 3C) elements of the device substrate 303 using an automated robotic device. The device substrate 303 and bonding material 360 are then positioned to receive a back glass substrate 361, which can be placed thereon by use of the same automated robotic device used to position the bonding material 360, or a second automated robotic device.

In one embodiment, prior to positioning the back glass substrate 361 over the bonding material 360, one or more preparation steps are performed on the back glass substrate 361 to assure that subsequent sealing processes and final solar product are desirably formed. In one case, the back glass substrate 361 is received in a “raw” state where the edges, overall size, and/or cleanliness of the substrate 361 are not well controlled. Receiving “raw” substrates reduces the cost to prepare and store substrates prior to forming a solar device and thus reduces the solar cell device cost, facilities costs, and production costs of the finally formed solar cell device. In one embodiment of step 130, the back glass substrate 361 surfaces and edges are prepared in a seaming module (e.g., front end seaming module 204) prior to performing the back glass substrate cleaning step. In the next sub-step of step 132, the back glass substrate 361 is transported to the glass cleaning module 230C in which a substrate cleaning step is performed on the substrate 361 to remove any contaminants on the surface of the substrate 361. Common contaminants may include materials deposited on the substrate 361 during the substrate forming process (e.g., glass manufacturing process) and/or during shipping of the substrates 361. Typically, the glass cleaning module 230C uses wet chemical scrubbing and rinsing steps to remove any undesirable contaminants as discussed above. The prepared back glass substrate 361 is then positioned over the bonding material 360 and the device substrate 303 by use of an automated robotic device.

Next, the device substrate 303, the back glass substrate 361, and the bonding material 360 are transported to the bonding module 232 in which lamination steps, or step 132, are performed to bond the back glass substrate 361 to the device substrate 303 formed in steps 102-130 discussed above. In step 132, the bonding material 360, such as Polyvinyl Butyral (PVB) or Ethylene Vinyl Acetate (EVA), is sandwiched between the back glass substrate 361 and the device substrate 303. Heat and pressure are applied to the structure to form a bonded and sealed device using various heating elements and other devices found in the bonding module 232.

The device substrate 303, the back glass substrate 361, and bonding material 360 thus form a composite solar cell structure 304 (FIG. 3D) that at least partially encapsulates the active regions of the solar cell device. In one embodiment, at least one hole, formed in the back glass substrate 361, remains at least partially uncovered by the bonding material 360 for each of the smaller solar cells 300 formed on the substrate 302. This allows portions of the cross-buss 356 or the side buss 355 to remain exposed so that electrical connections can be made to these regions of the composite solar cell structure 304 in future steps (i.e., step 138).

Next, the composite solar cell structure 304 is transported to the autoclave module 234 in which step 134, or autoclave steps are performed on the composite solar cell structure 304 to remove trapped gasses in the bonded structure and assure that a good bond is formed. In step 134, a composite solar cell structure 304 is inserted into the processing region of the autoclave module 234, where heat and high pressure gases are delivered to reduce the amount of trapped gas and improve the properties of the bond between the device substrate 303, back glass substrate 361, and the bonding material 360. The processes performed in the autoclave module 234 are also useful to assure that the stress in the glass and bonding layer (e.g., PVB layer) are controlled to prevent future failures of the hermetic seal or failure of the glass due to the stress induced during the bonding/lamination processes. In one embodiment, it may be desirable to heat the device substrate 303, back glass substrate 361, and bonding material 360 to a temperature that causes stress relaxation in one or more of the components in the composite solar cell structure 304.

Next, the composite solar cell structure 304 is transported to the junction box attachment module 236 in which junction box attachment steps 136 are performed on the composite solar cell structure 304. The junction box attachment module 236, used during step 136, is used to install a junction box 370 (FIG. 3C) on each of the smaller solar cells 300 formed on the substrate 302. The installed junction box 370 acts as an interface between the external electrical components that will connect to each formed solar cell, such as other solar cells or a power grid, and the internal electrical connections points, such as the leads, formed during step 128. In one embodiment, the junction box 370 contains one or more connection points 371, 372 so that each formed solar cell can be easily and systematically connected to other external devices to deliver the generated electrical power.

Next, the composite solar cell structure 304 is transported to the device testing module 238 in which device screening and analysis steps 138 are performed on the composite solar cell structure 304 to assure that the devices formed in the composite solar cell structure 304 meet desired quality standards. In one embodiment, the device testing module 238 is a solar simulator module that is used to qualify and test the output of the one or more formed smaller solar cells 300. In step 138, a light emitting source and probing device are used to measure the output of the formed smaller solar cells 300 by use of one or more automated components that are adapted to make electrical contact with terminals in the junction box 370. If the module detects a defect in the formed device, it can take corrective actions or the particular smaller solar cell 300 can be scrapped once sectioned from the other formed smaller solar cells in subsequent steps (i.e., step 140).

Next, the composite solar cell structure 304 is optionally transported to the sectioning module 240 in which a sectioning step 140 is used to section the composite solar cell structure 304 into a plurality of smaller solar cells 300 to form a plurality of smaller solar cell devices. In one embodiment, the composite solar cell structure 304 is sectioned along reference lines X-X and Y-Y, as shown in FIG. 3C. In one embodiment, the reference lines X-X and Y-Y are positioned at substantially the mid point of the sectioning region(s) 386. In one example, a composite solar cell structure 304 having an edge region 385 that is 10 mm wide and section region(s) 386 that are 20 mm wide allows each of the plurality of the formed smaller solar cells 300 to have edge regions 385 that are 10 mm wide, which surround the active portion of the solar cell 300. In one embodiment of step 140, the composite solar cell structure 304 is inserted into sectioning module 240 that uses a CNC glass cutting tool to accurately cut and section the composite solar cell structure 304 to form solar cell devices that are a desired size. In one embodiment, the composite solar cell structure 304 is inserted the sectioning module 240 that uses a laser cutting device to accurately cut and section the composite solar cell structure 304 to form solar cell devices that are a desired size. In one embodiment, the composite solar cell structure 304 is inserted into the sectioning module 240 that uses a glass scoring tool to accurately score the surface of the device substrate 302 and the surface of the back glass substrate 361. The composite solar cell structure 304 is then broken or laser cut along the scored lines to produce the desired size and number of fully formed and tested solar cell devices.

In one embodiment, the solar cell production line 200 is adapted to accept (step 102) and process substrate 302 or device substrates 303 that are 5.7 m² or larger. In one embodiment, these large area substrates 302 are fully processed and then sectioned into four 1.4 m² device substrates 303 during step 142. In one embodiment, the system is designed to process large device substrates 303 (e.g., TCO coated 2200 mm×2600 mm×3 mm glass) and produce various sized solar cell devices without additional equipment or processing steps. Currently amorphous silicon (a-Si) thin film factories must have one product line for each different size solar cell device. In the present invention, the production line 200 is able to manufacture different solar cell device sizes with minimal or no conversion time. In one aspect of the invention, the manufacturing line is able to provide a high solar cell device throughput, which is typically measured in Mega-Watts per year, by forming solar cell devices on a single large substrate and then sectioning the substrate to form solar cells of a more preferable smaller size.

This flexibility in output with a single input is unique in the solar thin film industry and offers significant savings in capital expenditure and reduction in processing complexity. The material cost for the input glass is also lower since solar cell device manufacturers can purchase a larger quantity of a single glass size to produce the various size solar cell devices. A more detailed description of exemplary sectioning modules 240 are presented below in the section entitled, “Sectioning Module and Processes.”

Next, each composite solar cell structure 304 is optionally transported to a back end seaming module 242 in which a seaming step 142 is used to prepare the edges of each composite solar cell structure 304 to reduce the likelihood of damage, such as chipping or crack initiation from the edge of the composite solar cell structure 304. In one embodiment, the back end seaming module 242 is used to round or bevel the edges of each composite solar cell structure 304. In one embodiment, a diamond impregnated belt or disc is used to grind the material from the edges of the composite solar cell structure 304. In another embodiment, a grinding wheel, grit blasting, or laser ablation technique is used to remove the material from the edges of the composite solar cell structure 304.

Next, each composite solar cell structure 304 is transported to the support structure module 244 in which support structure mounting steps 144 are performed on each composite solar cell structure 304 to provide a complete solar cell device that has one or more mounting elements attached to the composite solar cell structure 304 formed using steps 102-142 to a complete solar cell device that can easily be mounted and rapidly installed at a customer's site.

Next, the composite solar cell structure 304 is transported to the unload module 246 in which step 146, or device unload steps are performed to remove the formed smaller solar cells 300 from the solar cell production line 200.

In one embodiment of the solar cell production line 200, one or more regions in the production line are positioned in a clean room environment to reduce or prevent contamination from affecting the solar cell device yield and useable lifetime. In one embodiment, as shown in FIG. 2, a class 10,000 clean room space 250 is placed around the modules used to perform steps 108-118 and steps 128-132.

### Sectioning Module and Processes

The sectioning module 240 and processing sequence performed during the sectioning step 140 are used to section a large processed and tested composite solar cell structure 304 into two or more smaller composite solar cell structures 304, each containing a smaller solar cell 300. In one embodiment, the sectioning module 240 receives a 2600 mm×2200 mm composite solar cell structure 304 and sections it into two 1300 mm×2200 mm processed and tested composite solar cell structures 304. In one embodiment, the sectioning module 240 receives a 2600 mm×2200 mm composite solar cell structure 304 and sections it into two 2600 mm×1100 mm processed and tested composite solar cell structures 304. In one embodiment, the sectioning module 240 receives a 2600 mm×2200 mm composite solar cell structure 304 and sections it into four 1300 mm×1100 mm processed and tested composite solar cell structures 304.

In one embodiment, the system controller 290 (FIG. 2) controls the number and size of the sections of the composite solar cell structure 304 produced by the sectioning module 240. Accordingly, the system controller 290 sends commands to all downstream processes in the sequence 100 (FIG. 1) for coordinating both the processes and adjustments to the downstream modules to accommodate and further process sections of the composite structure 304 produced by the substrate sectioning module regardless of the size of the sections produced.

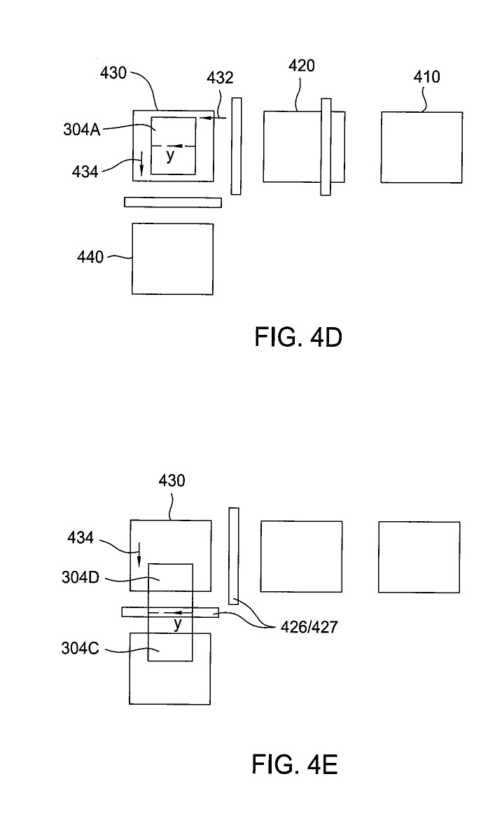

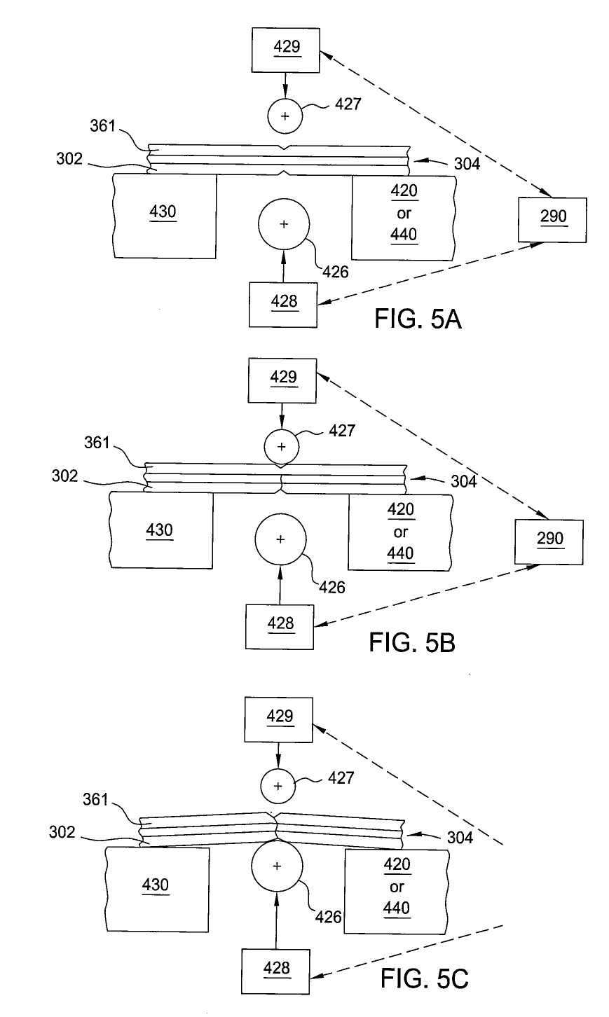

FIGS. 4A-4E are top plan, schematic views illustrating a sequence of sectioning a composite solar cell structure 304 according to one embodiment of the substrate sectioning module 240. Referring to FIG. 4A, an inlet conveyor 410 transports the composite solar cell structure 304 into a scoring station 420. In one embodiment, the back glass substrate 361 is facing upward and the substrate 302 is facing downward, as shown in FIGS. 5A-5C. A scoring station conveyor 422 positions the composite solar cell structure 304 in the scoring station 420 for scoring. In the scoring station 420, as shown in FIG. 4B, a pattern is scored on the upper surface of the back glass substrate 361 and the substrate 302 via a scoring mechanism 424 according to the programmed sectioning of the composite solar cell structure 304. In one embodiment, the inlet conveyor 410, the scoring station conveyor 422, and the scoring mechanism 424 are controlled and coordinated with each other as well as other operations in the sequence 100 (FIG. 1) via the system controller 290 (FIG. 2).

In one embodiment, the scoring mechanism 424 is a mechanical scoring mechanism, such as a mechanical scoring wheel. In one embodiment, the scoring mechanism 424 is an optical scoring mechanism, such a laser scoring mechanism.

The scored composite solar cell structure 304 is then transported via the scoring station conveyor 422 partially onto a cross transfer station 430 as shown in FIG. 4C. A first transfer station conveyor 432 is coordinated with the scoring station conveyor 422 via the system controller 290 to properly position the device substrate 303. FIGS. 5A-5C schematically illustrate a process for breaking the scored composite solar cell structure 304 according to one embodiment of the present invention. Referring to FIGS. 4C and 5A, the scored composite solar cell structure 304 is positioned over a roller 426 and under a roller 427 such that a line scored along the X-axis is located directly above the roller 426 and under the roller 427. The roller 427 is then lowered and placed in contact with the upper surface of the back glass substrate 361. As schematically shown in FIG. 5B, the roller 427 is lowered exerting a force on along the scored lines perpendicular to the plane of the composite structure resulting in a clean break in the glass substrate 302 along the scored line. The roller 426 is then raised and placed in contact with the lower surface of the substrate 303. As schematically depicted in FIG. 5C, the roller 426 is raised exerting a lifting force on the lower surface of the composite solar cell structure 304 along the scored line and perpendicular to the plane of the composite solar cell structure 304 resulting in a clean break along the scored line in the back glass substrate 361.

In one embodiment, the rollers 426 and 427 are padded cylindrical rollers extending the length of the composite solar cell structure 304. The roller 426 is raised by an actuator 428, and the roller 427 is lowered by an actuator 429. In one embodiment, the actuator 428 and the actuator 429 may each be an electric, hydraulic, or pneumatic motor. In one embodiment, the actuator 428 and the actuator 429 may each be a hydraulic or pneumatic cylinder. In one embodiment, the actuator 428 and the actuator 429 are each controlled and coordinated by the system controller 290.

Next, shown in FIG. 4D, a composite structure section 304A of the composite solar cell structure 304 is fully loaded into the cross transfer station 430 via the first transfer station conveyor 432. Next, a second transfer station conveyor 434, in conjunction with an exit conveyor 440, transfers the composite structure section 304A partially onto the exit conveyor 440 as shown in FIG. 4E. The second transfer station conveyor 434 is coordinated with the exit conveyor 440 via the system controller 290 to properly position the composite structure section 304A. Referring to FIGS. 4E and 5A, the composite structure section 304A is positioned over the roller 426 and under the roller 427 such that a line scored along the Y-axis is located directly above the roller 426 and below the roller 427. The roller 427 is then lowered and placed in contact with the upper surface of the composite structure section 304A. As schematically depicted in FIG. 5B, the roller 427 is lowered to exert a force on the upper surface of the composite structure section 304A along the scored line and perpendicular to the plane of the composite structure section 304A resulting in a clean break of the substrate 302. The roller 426 is then raised and placed in contact with the lower surface of the sectioned composite structure section 304A. As schematically depicted in FIG. 5C, the roller 426 is raised to exert a lifting force on the lower surface of the composite structure section 304A along the scored line and perpendicular to the plane of the composite structure section 304A resulting in a clean break along the scored line in the back glass structure 361. As a result the composite structure section 304A is sectioned into two smaller composite structure sections 304C and 304D. Each of the composite structure sections 304C and 304D are then transferred via the second transfer station conveyor 434 and the exit conveyor 440 into a subsequent module for further processing (steps 142-146). The above processes are then repeated for the composite structure section 304B.

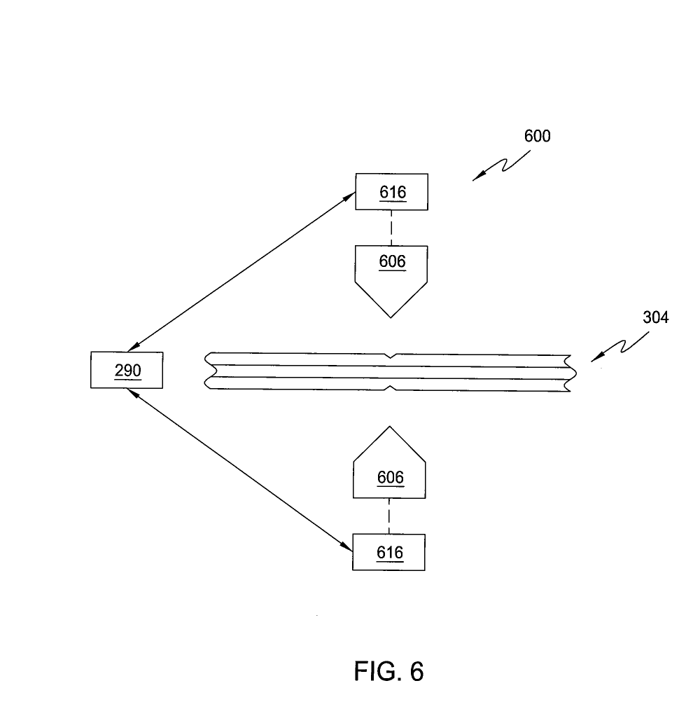

In one embodiment, rather than the above described break operations, the composite solar cell structure 304 is sectioned via a laser cutting process. FIG. 6 is a schematic depiction of a laser cutting device 600 sectioning the composite solar cell structure 304 along a scored line. The laser cutting device 600 may comprise a laser 606 positioned above the composite solar cell structure 304, below the composite solar cell structure 304, or both and a translation mechanism 616 for moving the laser 606. In one embodiment, the laser 606 is a carbon dioxide laser that can emit a continuous wave of radiation with the principal wavelength bands centering around about 9.4 μm and about 10.6 μm. The translation mechanism 616 may be any suitable linear actuator, such as a linear servo motor or the like. In one embodiment, the translation mechanism 616 is controlled by the controller 290 to control the cutting speed of the laser 606.

In one embodiment, after performing each of the above described break operations, it is further desirable to cut the bonding material 360 disposed between the glass substrate 302 and back glass substrate 361 to assure that the sectioned smaller solar cells 300 can be physically separated. In one embodiment, the process of cutting the bonding material 360 is performed in the sectioning module 240 by use of a cutting device (not shown), such as a knife, saw, cutting wheel, laser, or other similar device. In one embodiment, an additional step of cutting the bonding material 360 is performed after all of the breaking operations are performed. In another embodiment, the substrate cutting process is performed after each interim break operation step, such as after the first break operation shown in FIG. 4C and then again after the second break operation shown in FIG. 4E.

Although the above-described embodiment illustrates processes and apparatus for sectioning a single composite solar cell structure 304 into four smaller sections, it should be evident that the embodiment works equally well for sectioning a single composite solar cell structure 304 into two smaller sections by adjusting the scoring mechanism 424 to score only a single line on either the X-axis or the Y-axis and performing only a single break or cut process.

While the foregoing is directed to embodiments of the present invention, other and further embodiments of the invention may be devised without departing from the basic scope thereof, and the scope thereof is determined by the claims that follow.

1. A system for fabricating solar cell devices, comprising:
a substrate receiving module that is adapted to receive a front substrate;
a cluster tool having a processing chamber that is adapted to deposit a silicon-containing layer on a surface of the front substrate;
a back contact deposition chamber configured to deposit a back contact layer on the silicon-containing layer;
a bonding module configured to encapsulate the silicon-containing layer and the back contact layer between the front substrate and a back substrate into a composite structure;
a sectioning module configured to section the composite structure into two or more sections; and
a system controller for controlling and coordinating functions of each of the substrate receiving module, the cluster tool, the processing chamber, the back contact deposition chamber, the bonding module, and the sectioning module.

2. The system of claim 1, wherein the sectioning module comprises a CNC glass cutter.

3. The system of claim 1, wherein the sectioning module comprises a laser cutting device.

4. The system of claim 1, wherein the sectioning module comprises:
a scoring station configured to score a line into a surface of the composite structure;
a sectioning mechanism configured to split the composite structure along the line; and
a positioning mechanism for positioning the composite structure such that the line scored into the substrate is substantially aligned with the sectioning mechanism.

5. The system of claim 4, wherein the sectioning mechanism is a laser cutting device.

6. The system of claim 5, wherein the laser cutting device comprises a laser and a laser positioning mechanism.

7. The system of claim 4, wherein the sectioning mechanism is a break mechanism comprising a roller and an actuator configured to position the roller.

8. A system for fabricating solar cell devices, comprising:
a substrate receiving module that is adapted to receive a front substrate;
a cluster tool having a processing chamber that is adapted to deposit a silicon-containing layer on a surface of the front substrate;
a back contact deposition chamber configured to deposit a back contact layer on the silicon-containing layer;
a bonding module configured to encapsulate the silicon-containing layer and the back contact layer between the front substrate and a back substrate into a composite structure;
a testing module configured to test performance characteristics of the composite structure;
a sectioning module configured to section the tested composite structure into two or more sections, wherein the sectioning module comprises a composite structure positioning mechanism and a composite structure sectioning mechanism; and
a system controller for controlling and coordinating functions of each of the substrate receiving module, the cluster tool, the processing chamber, the back contact deposition chamber, the bonding module, the testing module, and the sectioning module.

9. The system of claim 8, wherein the sectioning mechanism is a CNC glass cutting device.

10. The system of claim 8, wherein the sectioning mechanism is a laser cutting device.

11. The system of claim 8, wherein the composite structure positioning mechanism comprises:
an inlet conveyor configured to receive commands from the system controller and transfer the composite structure into a scoring station of the sectioning module; and
a first positioning device configured to receive commands from the system controller and accurately position the scored composite structure with respect to a first sectioning device of the sectioning mechanism.

12. The system of claim 11, wherein the first sectioning device is a laser cutting device comprising a laser and a laser positioning mechanism.

13. The system of claim 11, wherein the first sectioning device is a break mechanism comprising a roller and a roller positioning mechanism.

14. The system of claim 11, wherein the composite structure positioning mechanism further comprises:
a second positioning device configured to receive commands from the system controller and accurately position a section of the scored composite structure with respect to a second sectioning device of the sectioning mechanism; and
an exit conveyor configured to receive commands from the system controller and transfer a portion of the section of the scored composite structure out of the sectioning module.

15. The system of claim 14, wherein the second sectioning device is a laser cutting device comprising a laser and a laser positioning mechanism.

16. The system of claim 14, wherein the second sectioning device is a break mechanism comprising a roller and a roller positioning mechanism.

17. A method of processing a solar cell device, comprising:
cleaning a substrate to remove one or more contaminants from a surface of the substrate;
depositing a photoabsorbing layer on the surface of the substrate;
removing at least a portion of the photoabsorbing layer from a region on the surface of the substrate;
depositing a back contact layer over the photoabsorbing layer on the substrate;
removing at least a portion of the back contact layer and the photoabsorbing layer from a region on the surface of the substrate;
bonding a back glass substrate to the substrate to form a composite structure, wherein the back contact layer and the photoabsorbing layer are bonded between the back glass substrate and the substrate;
attaching one or more junction boxes to the composite structure;
testing performance characteristics of the composite structure; and
sectioning the composite structure into two or more sections.

18. The method of claim 17, wherein sectioning the composite structure comprises cutting the composite structure with a CNC glass cutter.

19. The method of claim 17, wherein sectioning the composite structure comprises cutting the composite structure with a laser cutting device.

20. The method of claim 17, wherein sectioning the composite structure comprises scoring one or more lines in one or more surfaces of the composite structure and sectioning the composite structure along the one or more scored lines.
